(19) United States
(12) Patent Application Publication
(10) Pub. No.: US 2026/0089915 A1
(43) Pub. Date: Mar. 26, 2026

(54) DYNAMIC RANDOM ACCESS MEMORY (DRAM) WITH BACKEND TRANSISTORS

(71) Applicant: Intel Corporation, Santa Clara, CA (US)

(72) Inventor: Abhishek A. Sharma, Portland, OR (US)

(73) Assignee: Intel Corporation, Santa Clara, CA (US)

(21) Appl. No.: 18/897,213

(22) Filed: Sep. 26, 2024

(51) Int. Cl. H10B 12/00

(52) U.S. Cl. CPC H10B 12/315; H10B 12/36

(57) ABSTRACT

A dynamic random-access memory (DRAM) device has a layer of backend transistors that are formed over the DRAM array. For example, the backend transistors may include channel regions or other transistor structures that are in direct contact with an etch stop layer formed over the DRAM array. The backend transistors may increase the amount of surface area that can be utilized for memory cells by moving transistors for implementing power gating, SRAM tags, or other features to a backend layer that is over the storage capacitors. Low temperature processes may be used to fabricate the backend transistors while minimizing damage to frontend structures.

### BACKGROUND

Embedded memory is important to the performance of modern system-on-a-chip (SoC) technology. Typically, memory assemblies (e.g., static random-access memory (SRAM) and dynamic random-access memory (DRAM)) include transistors arranged in a single layer. Low power and high-density embedded memory is used in many different computer products and further improvements are always desirable.

A DRAM memory cell typically includes a capacitor for storing a bit value or a memory state (e.g., logical “1” or “0”) of the cell and an access transistor controlling access to the cell (e.g., access to write information to the cell or access to read information from the cell). Such a memory cell may be referred to as a “1T-1C memory cell,” highlighting the fact that it uses one transistor (i.e., “1T” in the term “1T-1C memory cell”) and one capacitor (i.e., “1C” in the term “1T-1C memory cell”). The capacitor of a 1T-1C memory cell may be coupled to one source/drain (S/D) region/terminal of the access transistor (e.g., to the source region of the access transistor), while the other S/D region of the access transistor may be coupled to a bitline (BL), and a gate terminal of the transistor may be coupled to a wordline (WL).

### BRIEF DESCRIPTION OF THE DRAWINGS

Embodiments will be readily understood by the following detailed description in conjunction with the accompanying drawings. To facilitate this description, like reference numerals designate like structural elements.

Embodiments are illustrated by way of example, and not by way of limitation, in the figures of the accompanying drawings.

FIGS. 1A and 1B illustrate example perspective views and side views of dies formed over a wafer, according to some embodiments of the present disclosure.

FIG. 2 provides a schematic illustration of a DRAM device with transistors formed on the backend, according to some embodiments of the present disclosure.

FIG. 3 provides a cross-section of the DRAM device with backend transistors of FIG. 2, according to some embodiments of the present disclosure.

FIGS. 4A and 4B illustrate two cross-sections of the interface between the DRAM layer and backend transistor layer, according to some embodiments of the present disclosure.

FIG. 5 is a cross-section view of another example interface between the DRAM layer and the backend transistor layer with backside contacts to the transistor layer, according to some embodiments of the present disclosure.

FIG. 6 is a cross-section view illustrating example interconnects through an etch stop layer of the DRAM layer, according to some embodiments of the present disclosure.

FIG. 7 is a cross-section view illustrating another example of an interconnect through an etch stop layer of the DRAM layer, according to some embodiments of the present disclosure.

FIGS. 8A and 8B are top views of a wafer and dies that may include or be used with a DRAM device with backend transistors in accordance with any of the embodiments disclosed herein.

FIG. 9 is a cross-sectional side view of an IC device that may be included in a DRAM device with backend transistors in accordance with any of the embodiments disclosed herein.

FIG. 10 is a cross-sectional side view of an IC device assembly that may include a DRAM device with backend transistors in accordance with any of the embodiments disclosed herein.

FIG. 11 is a block diagram of an example computing device that may include one or more a DRAM device with backend transistors in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

One challenge with DRAM cells is that, given a usable surface area of a substrate, there are only so many transistors that can be formed in that area, placing a significant limitation on the density of memory cells incorporating such transistors. In conventional solutions, attempts to increase memory density have included decreasing the critical dimensions of the memory cells, which requires ever-increasing process complexity and cost, resulting in diminishing returns and expected slow pace of memory scaling for future nodes.

Embodiments of the present disclosure may increase the amount of surface area that can be utilized for memory cells by moving at least a portion of the transistors to a backend layer that is over the storage capacitors. As noted above, a DRAM array may include, for each memory cell, an access transistor and a capacitor. In addition, a DRAM device may include additional transistors to enable power gating, implement SRAM tags, and/or provide access circuits, for example.

As described herein, low-temperature processing may be used to build transistors for these or other features on the backend of the DRAM array, e.g., in a layer over the capacitors. For example, a semiconductor material may be layer-transferred directly over a DRAM layer, and low-temperature semiconductor fabrication steps (e.g., low-temperature deposition processes, such as low-temperature epitaxy) may be performed to form transistors around the layer-transferred semiconductor material. An interconnect stack may then be formed over the backend transistor layer to form memory and/or logic circuits with the backend transistors.

An IC device includes various circuit elements, such as transistors and capacitors, coupled together by metal interconnects. The circuit elements and metal interconnects may be formed in different layers. In particular, one or more layers of an IC device in which transistors and other IC components are implemented may be referred to as a “transistor layer” or “device layer”. Layers with conductive interconnects for providing electrical connectivity (e.g., in terms of signals and power) to the transistors and/or other devices of the transistor layer of the IC device may be referred to as a “metal layer,” “metallization layer,” or “interconnect layer”. For example, the device layer may be a front-end-of-line (FEOL) layer, while the metal layers may be back-end-of-line (BEOL) layers formed over the FEOL layer. In general, the transistor layer and the metal layers may be provided in any layers of an IC device as long as they are in different planes (e.g., at different distances from) a support structure (e.g., a die, a chip, a substrate, a carrier substrate, or a package substrate) of the IC device, or some other reference plane.

Typically, an IC device includes a metallization stack, which is a collection of several metal layers, stacked above one another, in which different interconnects are provided. The interconnects include electrically conductive trenches, also referred to as lines, which provide connectivity across the layer, and electrically conductive vias (or, simply, “vias”) that provide electrical connectivity between different layers. In general, the term “trench” or “line” may be used to describe an electrically conductive element isolated by an insulator material (e.g., an insulator material typically comprising a low-k dielectric) that is provided in a plane parallel to the plane of an IC die/chip or a support structure over which an IC structure is provided, while the term “via” may be used to describe an electrically conductive element that interconnects two or more trenches of different levels of a metallization stack, or a component of the transistor layer and one or more trenches of a metallization layer. To that end, a via may be provided substantially perpendicularly to the plane of an IC die/chip or a support structure over which an IC structure is provided, and the via may interconnect two trenches in adjacent levels, two trenches in not adjacent levels, and/or a component of a transistor layer and a trench in adjacent or not adjacent layers. Sometimes, trenches and vias may be referred to as “metal trenches/tracks/lines/traces” and “metal vias”, respectively, to highlight the fact that these elements include electrically conductive materials such as, but not limited to, metals. Together, trenches and vias may be referred to as “interconnects,” “interconnect structures,” or “conductive structures,” where these terms may be used to describe any element formed of an electrically conductive material for providing electrical connectivity to/from one or more components associated with an IC or/and between various such components.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.” The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g. logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

In the following, some descriptions may refer to a particular S/D region or contact being either a source region/contact or a drain region/contact. However, unless specified otherwise, which region/contact of a transistor is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

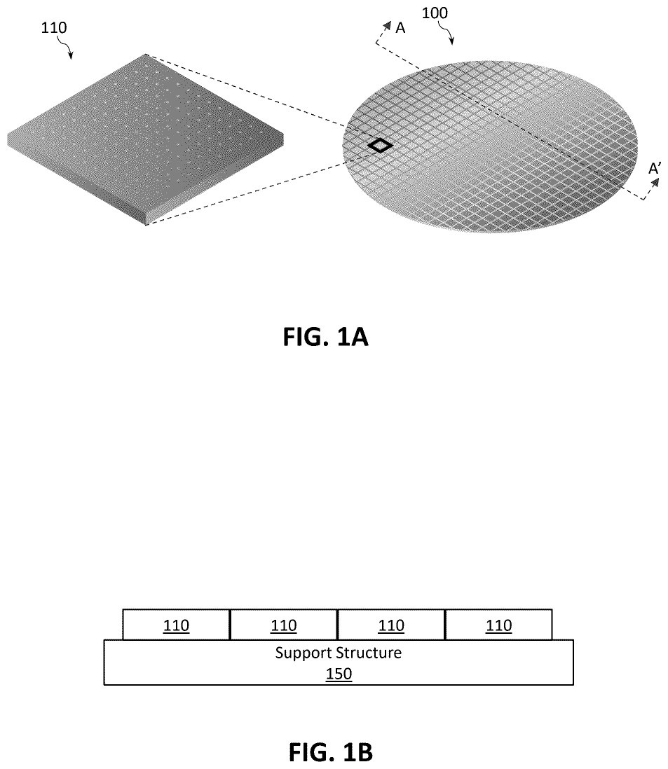

For convenience, if a collection of drawings designated with different letters are present, e.g., FIGS. 1A-1B, such a collection may be referred to herein without the letters, e.g., as “FIG. 1.”

### Example Wafer with Multiple DRAM Dies

FIGS. 1A and 1B illustrate example perspective views and side views of dies formed over a wafer, according to some embodiments of the present disclosure. For example, the wafer may include DRAM arrays arranged on a plurality of dies over the wafer. The wafer 100 may be generally circular or approximately circular.

In the drawings, some example structures of various devices and assemblies described herein are shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

The wafer 100 may be composed of semiconductor material and include multiple dies having IC structures (e.g., transistors and capacitors) formed on a surface of the wafer 100. One of the dies 110 is labelled and enlarged in FIG. 1A, but a plurality of similar dies are shown to be arranged in a grid-like manner across the wafer 100. Each of the dies of the wafer 100 may be a repeating unit of a semiconductor product that includes any suitable IC. The dies 110 may include semiconductor devices implementing DRAM memory cells. Individual dies 110 may further include circuitry for connecting these devices, e.g., interconnect circuitry that may include lines (or trenches) and vias. The interconnect circuitry is typically formed from conductive materials, and may be formed in one or more interconnect layers, also referred to as metal layers.

Within a given die, the interconnect layers are referred to herein as local interconnect layers, meaning that the interconnect structures are local to a die 110, rather than extending between multiple dies. The semiconductor devices may be formed in one or more layers, e.g., a layer of storage capacitors over a layer of access transistors. The dies 110 may be rectangular or square shaped. The dies 110 may be separated from each other by small spaces (e.g., less than 500 microns, or less than 200 microns) forming a grid, visible in FIG. 1A. These spaces are referred to as scribe lines, and typically do not include active circuitry.

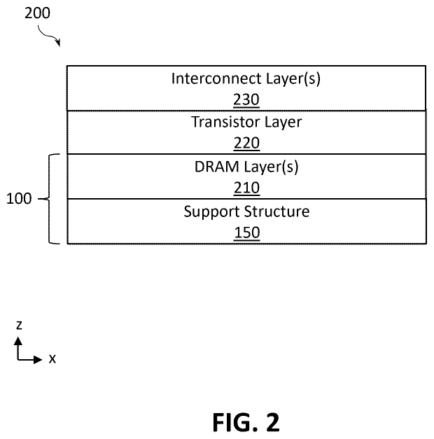

The wafer 100 may represent a DRAM wafer, over which backend transistors may be formed, e.g., as described with respect to FIGS. 2-7. The backend processing (e.g., forming the transistors and one or more interconnect layers) may be performed across the DRAM wafer 100, including over each of the dies 110. Following the backend processing, a process to singulate the dies may be performed, resulting in a set of DRAM dies with backend transistors. For example, dies may be individuated from each other using mechanical blade dicing to scribe lines along the boundaries of the dies, e.g., at the locations of the boundaries shown in FIG. 1. As another example, a laser beam may be used to ablate and remove material along the boundaries of the dies. Still other techniques for singulating dies include plasma etching and dry etching.

FIG. 1B illustrates an example cross-section of a wafer 100, taken through the plane AA′ illustrated in FIG. 1A. In this example, the wafer 100 includes a support structure 150 over which multiple dies 110 are formed. While four dies 110 are illustrated in FIG. 1B, it should be understood that more dies, or fewer dies, maybe included in the cross-section. In this example, the dies 110 are arranged over the support structure 150. For example, the dies 110 may be built up over the support structure 150. In some embodiments, the dies 110 may be formed fully or partially in the support structure 150, rather than resting on top of the support structure 150 as shown in FIG. 1B. In some cases, the dies 110 may be fabricated, tested, and then mounted onto the support structure 150.

The support structure 150 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. Although a few examples of materials from which the substrate may be formed are described here, any material that may serve as a foundation upon which a full wafer device as described herein may be built falls within the spirit and scope of the present disclosure.

### Example Dram With Backend Transistors

FIG. 2 provides a schematic illustration of a DRAM device 200 with transistors formed on the backend, according to some embodiments of the present disclosure. The DRAM device 200 may be a wafer that includes backend transistors formed over the DRAM arrays. As described above, following backend processing, the DRAM device 200 may be diced to form individuated dies, e.g., DRAM dies with backend transistors.

The DRAM device 200 includes the support structure 150 described in relation to FIG. 1. The DRAM device 200 further includes one or more DRAM layer(s) 210, which may be arranged as one or more dies, e.g., the dies 110 of FIG. 1. The support structure 150 and DRAM layer(s) 210 jointly form the DRAM wafer 100, described above.

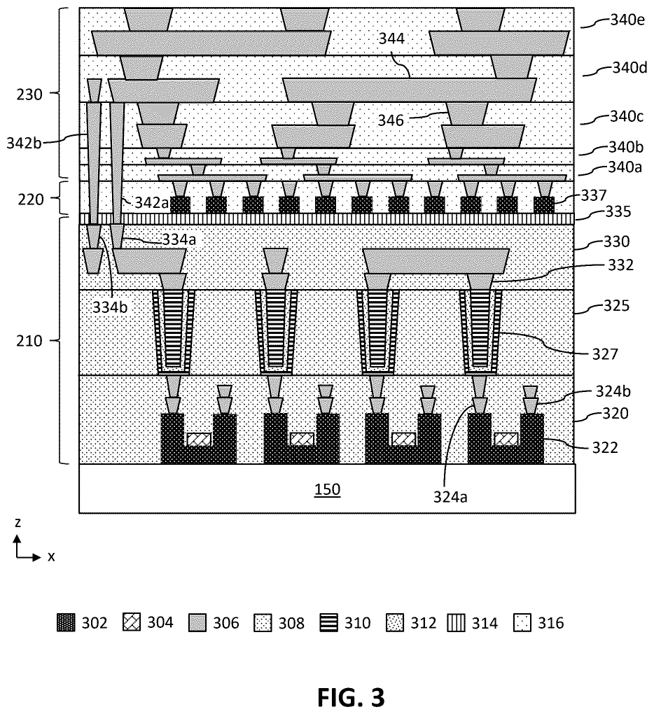

A DRAM layer 210 may include an array of 1T-1C memory cells. A cross-section of an example DRAM layer 210 is illustrated in FIG. 3. In some embodiments, the DRAM wafer 100 may include multiple DRAM layers 210, e.g., a first DRAM layer with a first DRAM array, and a second DRAM layer with a second DRAM array over the first DRAM layer. In some arrangements, an array of access transistors may be used to access two or more DRAM layers, e.g., a particular access transistor may be used to access a first capacitor in a first DRAM layer and/or a second capacitor in a second DRAM layer over the first DRAM layer. Other layered DRAM arrangements may be used. In general, the DRAM layer(s) 210 are referred to herein as a DRAM layer 210, but it should be understood that the DRAM layer 210 may include multiple layers, e.g., multiple layers of DRAM arrays, or capacitors arranged within multiple layers.

A transistor layer 220 is formed over the DRAM layer 210. A cross-section of an example transistor layer 220 is illustrated in FIG. 3. The transistor layer 220 includes a plurality of transistors. The transistor layer 220 may additionally or alternatively include other devices, e.g., other semiconductor devices, such as diodes. The DRAM layer 210 and the transistor layer 220 generally extend in the x-y plane in the coordinate system shown in FIG. 2 and used in the other figures. As with the DRAM layer 210, the transistor layer 220 may be arranged in a plurality of dies (e.g., the dies 110). The transistor layer 220 is also referred to as a backend transistor layer due to the processing stage at which the transistor layer 220 is formed.

In semiconductor device processing, frontend processing steps are performed earlier on, while backend processing steps are performed later. For example, front-end-of-line (FEOL) processing generally includes formation of semiconductor devices (e.g., transistors), which may include patterning a semiconductor substrate, performing epitaxial deposition, gate fabrication, etc. In the case of a DRAM device, the frontend processing may include forming the access transistors and the storage capacitors. Frontend processing can require high temperatures at the deposition stages.

Back-end-of-line (BEOL) processing, typically includes forming interconnect layers over the semiconductor devices formed during the frontend processing. The BEOL stages include depositing dielectric layers and forming metal interconnects (vias and trenches) within the dielectric layers. Further backend or postfab processing can take a finished wafer (e.g., a wafer after FEOL and BEOL processing) and perform the steps of wafer testing, wafer grinding, die separation, and IC packaging.

In this example, the transistor layer 220 is performed as a backend processing step, after FEOL and BEOL processing of the DRAM wafer 100. The transistor layer 220 is formed directly over the DRAM layer 210. For example, a top layer of the DRAM layer 210 (i.e., the layer opposite the support structure 150) is an etch stop layer, and the transistor layer 220 is formed directly on the etch stop layer. The transistor layer 220 may include transistor structures, such as semiconductor channels, that are in direct contact with the etch stop layer.

The transistors in the transistor layer 220 may be formed using low-temperature processes that preserve the DRAM layer 210. Previously, certain stages in semiconductor device fabrication (e.g., epitaxial deposition) used high temperatures that can damage metal layers, e.g., causing diffusion of typical interconnect materials such as copper, tungsten, and aluminum. To avoid damaging the metal layers, the BEOL processing was performed after the higher-temperature FEOL processing. Newer low-temperature deposition process, such as low-temperature epitaxy, enable formation of semiconductor devices at the backend, without damaging underlying components, such as a previously-formed interconnect stack.

The DRAM device 200 further includes one or more interconnect layers 230 formed over the transistor layer 220. The interconnect layers 230 may connect to circuitry within a given die, i.e., a set of transistors are formed over each of the dies 110, and a local interconnect structure is then formed over each of the dies 110, and further over the transistors. A cross-section of an example stack of interconnect layers 230 is illustrated in FIG. 3. Following formation of the interconnect layers 230, the DRAM device 200 may be diced to form individuated DRAM dies, as described above.

The DRAM device 200 may include additional layers not specifically illustrated in FIG. 2. For example, the DRAM device 200 may include a power delivery structure formed on the back side of the support structure 150 or over the interconnect layer 230. The power delivery structure may include passive devices, e.g., inductors, resistors, and/or capacitors, e.g., to reduce EMI and/or suppress ESD in the power delivery structure. The power delivery structure may be configured to be coupled to an external device that provides power for the DRAM device 200.

The transistor layer 220 and connected interconnect layers 230 may provide enhanced features for the DRAM device 200. For example, one or more of the interconnect layers 230 may connect sets of transistors in the transistor layer 220 to form SRAM cells. An SRAM cell for storing a single bit of data typically includes six transistors. The SRAM cells may implement SRAM tags that index memory locations in the DRAM array. Compared to DRAM, SRAM provides relatively faster access times, which can be useful for storing an address space for the DRAM as it improves overall performance of the DRAM device. However, SRAM cells are relatively large, and if included in the same layer as the DRAM, can consume a lot of area. Thus, moving the SRAM tags to a backend layer removes the area penalty previously associated with SRAM tags.

As another example, the transistors in the transistor layer 220 can implement power and/or access logic for the DRAM device 200. For example, transistors in the transistor layer 220 can implement power gating. This refers to coupling a transistor to the gate of a set of access transistors, so that power to the set of access transistors can be switched on and off. Power gating can reduce overall power consumption of the DRAM device 200. As with SRAM tags, moving the power gating control to a second layer removes the area penalty of power gating circuitry.

### Example Cross-Sections of Dram Device with Backend Transistors

FIG. 3 provides a cross-section of the DRAM device with backend transistors of FIG. 2, according to some embodiments of the present disclosure. FIG. 3 shows a cross-section in an x-z plane in the orientation of FIGS. 2 and 3. FIG. 3 illustrates cross sections of the support structure 150, the DRAM layer 210, the transistor layer 220, and the interconnect layers 230. A number of elements referred to in the description of FIG. 3 with reference numerals are illustrated in these figures with different patterns, with a legend showing the correspondence between the reference numerals and patterns being provided at the bottom of the drawing page. The legend in FIG. 3 illustrates that FIG. 3 uses different patterns to show a semiconductor material 302, a gate electrode 304, a conductive material 306, a first dielectric material 308, a capacitor electrode material 310, a capacitor insulator 312, an etch stop material 314, and a second dielectric material 316.

The DRAM layer 210 includes a DRAM array, which generally includes a set of transistors coupled to a set of capacitors, forming 1T-1C memory cells. DRAM arrays may have various forms and architectures. In the example shown in FIG. 3, the DRAM layer 210 includes an access transistor layer 320 that includes a set of transistors, e.g., the transistor 222; a capacitor layer 325 that includes a set of capacitors, e.g., the capacitor 327; an interconnect layer 330; and an etch stop layer 335. The etch stop layer 335 is at the top of the DRAM layer 210. In various embodiments, the interconnects, capacitors, and transistors may be arranged differently than shown in FIG. 2; for example, the access transistors may be next to or above the capacitors, and one or more interconnect layers may be below the access transistors and/or between the access transistors and the capacitors.

The transistors in the access transistor layer 320 may have any transistor architecture. For example, the transistors may be planar transistors, thin film transistors, or three-dimensional transistors, such as fin-shaped transistors or nanoribbon-shaped transistors. In the example of FIG. 3, the transistor 322 is a three-dimensional transistor with a recessed gate. Compared to other transistor architectures, the recessed gate design provides a longer channel length between a source and drain region while maintaining transistor density across a device. The recessed gate structure results in a longer path between the source and drain regions, which reduces leakage current.

The transistor 322 includes a semiconductor material 302 and a gate electrode 304. More generally, the transistor 322 may include a gate stack that includes a gate dielectric (not specifically shown) over the semiconductor material 302 and the gate electrode 304 over the gate dielectric. The semiconductor material 302 has a recess, and the gate stack (including the gate electrode 304) extends through the recess. Two source/drain (S/D) regions (not specifically shown) may be formed on either side of the recess and alongside and/or above the gate electrode 304. A pair of contact electrodes 324a and 324b are coupled to the S/D regions of the transistor 322.

The semiconductor material 302 may be composed of semiconductor material systems including, for example, N-type or P-type materials systems. In some embodiments, the semiconductor material 302 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the semiconductor material 302 may include a combination of semiconductor materials. In some embodiments, the semiconductor material 302 may include a monocrystalline semiconductor, such as silicon (Si) or germanium (Ge). In some embodiments, the semiconductor material 302 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (e.g., for the embodiments where the transistor 322 is an N-type metal oxide semiconductor (NMOS) transistor), the semiconductor material 302 may include a III-V material having a relatively high electron mobility, such as, but not limited to InGaAs, InP, InSb, and InAs. For some such embodiments, the semiconductor material 302 may be a ternary III-V alloy, such as InGaAs, GaAsSb, InAsP, or InPSb. For some InₓGa₁₋ₓAs embodiments, In content (x) may be between 0.6 and 0.9, and may advantageously be at least 0.7 (e.g., In_{0.7}Ga_{0.3}As). For some example P-type transistor embodiments (e.g., for the embodiments where the transistor 322 is a P-type metal oxide semiconductor (PMOS) transistor), the semiconductor material 302 may advantageously be a group IV material having a high hole mobility, such as, but not limited to Ge or a Ge-rich SiGe alloy. For some example embodiments, the semiconductor material 302 may have a Ge content between 0.6 and 0.9, and advantageously may be at least 0.7.

In some embodiments, the semiconductor material 302 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if a transistor is a thin-film transistor (TFT), the semiconductor material 302 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N-or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. The semiconductor material 302 may have a thickness between about 5 and 75 nanometers, including all values and ranges therein, e.g., between about 5 and 30 nanometers.

The gate electrode 304 may include at least one P-type work function metal or N-type work function metal, depending on whether the gate electrode 304 is to be included in a P-type transistor or an N-type transistor. For a P-type transistor, metals that may be used for the gate electrode 304 may include, but are not limited to, ruthenium, palladium, platinum, cobalt, nickel, and conductive metal oxides (e.g., ruthenium oxide). For an N-type transistor, metals that may be used for the gate electrode 304 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 304 may include a stack of two or more metal layers, where one or more metal layers are work function metal layers and at least one metal layer is a fill metal layer. Further metal layers may be included for other purposes, such as to act as a barrier layer.

A gate dielectric stack may include a high-k dielectric and an insulator material, arranged in the gate stack so that the insulator material is disposed between the high-k dielectric and the semiconductor material 302, and the high-k dielectric is between the insulator material and the gate electrode 304. The insulator material may be in contact with the semiconductor material 302, and may provide the interface between the semiconductor material 302 and the high-k dielectric. In various embodiments, the insulator material may have a dielectric constant lower than that of the high-k dielectric. In some embodiments, the insulator material may include silicon and oxygen. In other embodiments, the insulator material may include IGZO. In some embodiments, the insulator material may be an amorphous, crystalline, or semi crystalline oxide semiconductor. In some embodiments, the insulator material may be in contact with the high-k dielectric, while in other embodiments, an intermediate material may be disposed between the insulator material and the high-k dielectric. The insulator material may have a thickness between 0.5 nanometers and 5 nanometers (e.g., between 5 angstroms and 3 nanometers, or between 6 angstroms and 3 nanometers).

The high-k dielectric may include elements such as hafnium, silicon, oxygen, titanium, tantalum, lanthanum, aluminum, zirconium, barium, strontium, yttrium, lead, scandium, niobium, and zinc. Examples of high-k materials that may be used in the high-k dielectric may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the high-k dielectric during manufacture of the DRAM layer 210 to improve the quality of the high-k dielectric. The high-k dielectric may have a thickness that may be between 0.5 nanometers and 3 nanometers (e.g., between 1 and 3 nanometers, or between 1 and 2 nanometers).

As noted above, the transistor 322, and particularly, S/D regions of the transistor 322, are coupled to a pair of contact electrodes 324a and 324b. The contact electrodes 324 are formed from the conductive material 306. The conductive material 306 may include any appropriate conductive material, such as copper, silver, nickel, gold, aluminum, tungsten, other metals, or metal alloys, for example.

The conductive material 306 provides electrical connections between the transistors (e.g., transistor 322) and capacitors (e.g., the capacitor 327). For example, in a DRAM array, one S/D region of the access transistor is coupled to one of the electrodes of the capacitor 327, e.g., via the contact electrode 324a. The other S/D region is coupled to a bitline (BL) (e.g., via the contact electrode 324b), and the gate electrode 304 is coupled to a wordline (WL). Lastly, the other electrode of the capacitor 327 is coupled to a plateline (PL).

The capacitor 327 includes two electrodes. In this example, the capacitors in the capacitor layer 325 have a nested structure, in which a first capacitor electrode of the capacitor electrode material 310 extends along a base and the sides of the capacitor, a layer of the capacitor insulator 312 is nested inside the first capacitor electrode, and a second capacitor electrode of the capacitor electrode material 310 is nested inside the capacitor insulator 312. In other embodiments, different capacitor architectures may be used.

The capacitor electrode material 310 may include any suitable electrically conductive material, which may include a metal, an alloy, or a stack of multiple electrically conductive materials. In some embodiments, such electrically conductive materials may include one or more metals or metal alloys, with metals such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, the capacitor electrode material 310 may include one or more electrically conductive alloys, oxides, or carbides of one or more metals. In some embodiments, the capacitor electrode material 310 may include a doped semiconductor, such as silicon or another semiconductor doped with an N-type dopant or a P-type dopant.

The capacitor insulator 312 may include dielectric materials known for their applicability in ICs, such as low-k dielectric materials. Examples of dielectric materials that may be used as the capacitor insulator 312 may include, but are not limited to, silicon dioxide (SiO2), carbon-doped oxide (CDO), silicon nitride, fluorosilicate glass (FSG), silicon nitride, and organosilicates such as silsesquioxane, siloxane, or organosilicate glass. In some embodiments, the capacitor insulator 312 may include organic polymers such as polyimide, polynorbornenes, benzocyclobutene, perfluorocyclobutane, or polytetrafluoroethylene (PTFE). Still other examples of low-k dielectric materials that may be used as the capacitor insulator 312 include silicon-based polymeric dielectrics such as hydrogen silsesquioxane (HSQ) and methylsilsesquioxane (MSQ).

The interconnect layer 330 is over the capacitor layer 325. The interconnect layer 330 includes conductive structures, such as vias and trenches, formed from the conductive materials 306. Conductive structures (e.g., vias) may be coupled to the second capacitor electrodes (e.g., the inner electrodes in the depicted nested structure). For example, the via 332 is coupled to the second electrode of the capacitor 327; the via 332 may further couple the second electrode of the capacitor 327 to a plateline. While one interconnect layer 330 is shown in FIG. 3, the logic layer 210 may have a stack of multiple interconnect layers, e.g., as shown in the interconnect layers 230 and described below.

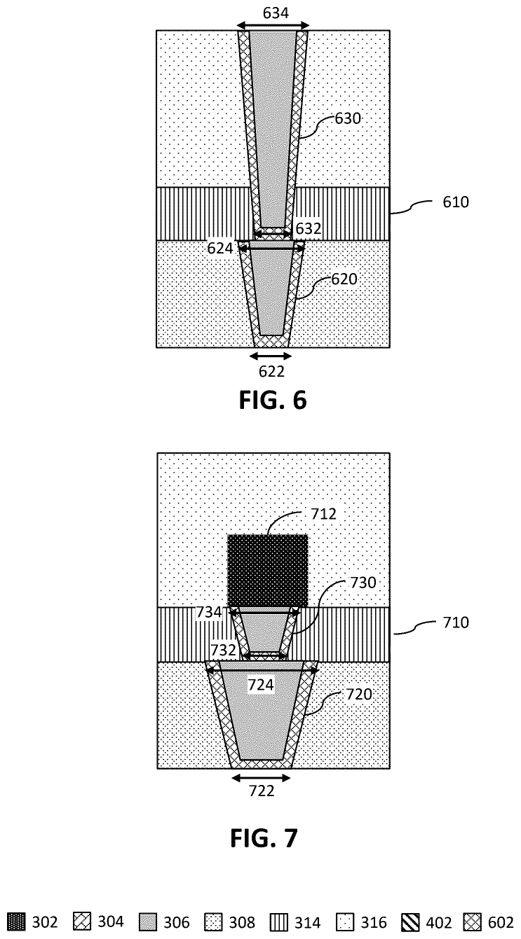

In this example, the interconnect layer 330 includes vias 334a and 334b that are directly below the etch stop layer 335. Vias 342a and 342b in the interconnect layers 230 extend through the etch stop layer 335 and are electrically coupled to (here, in direct physical and electrical contact with) the vias 334a and 334b, respectively, providing connectivity between the DRAM layer 210 and the backend transistor layer 220 (via the interconnect layers 230). FIG. 6, discussed below, illustrates a connection between a via 334 and a via 342 in greater detail.

In this example, the first dielectric material 308 is formed around the access transistor layer 320, capacitor layer 325, and interconnect layer 330 of the DRAM layer 210. The first dielectric material 308 may be any suitable dielectric material, such as any of the dielectric materials described herein. In some embodiments, different layers include different dielectric materials, e.g., the interconnect structures in the interconnect layer 330 may be formed in a different dielectric material from the capacitors in the capacitor layer 325.

The etch stop layer 335 is along an upper surface of the DRAM layer 210, at an opposite side of the DRAM layer 210 from the support structure 150. In this example, the etch stop layer 335 is over the interconnect layer 330. The etch stop layer 335 includes the etch stop material 314, which is a dielectric material that provides high etch selectivity relative to other materials which may be layered over the etch stop layer 335. The etch stop material 314 may include silicon, nitrogen, and/or carbon. For example, an etch stop material that includes silicon, nitrogen, and carbon, where the atomic percentage of any of these materials may be at least 1%, e.g., SiOCN, may be advantageous in terms that such a material may act both as an etch-stop material, and have sufficient adhesive properties to bond the DRAM layer 210 to a semiconductor material that is layer-transferred over the DRAM layer 210. In addition, an etch-stop material at the interface between the DRAM layer 210 and the transistor layer 220 that includes include silicon, nitrogen, and carbon, where the atomic percentage of any of these materials may be at least 1%, may be advantageous in terms of improving etch-selectivity of this material with respect to other materials in these layers.

The transistor layer 220 is directly over the etch stop layer 335. The transistor layer 220 includes a set of transistors, e.g., the transistor 337. In this example, the transistors in the transistor layer 220 include the semiconductor material 302. In general, the transistors may include any semiconductor material suitable for forming a semiconductor channel (e.g., of the semiconductor materials 302 described above), along with source/drain materials (e.g., epitaxially deposited semiconductor materials, which may have higher dopant concentrations than the semiconductor material 302) and gate materials (e.g., the gate dielectric and gate electrode materials described above). The transistors, e.g., the transistor 337, may have any architecture, such as any of the options described above.

The transistor layer 220 may be fabricated directly over the DRAM layer 210 using a low-temperature fabrication process. In some embodiments, a layer of the semiconductor material 302 is layer-transferred onto the DRAM layer 210, and more specifically, onto the etch stop layer 335. The layer-transferred semiconductor material is then etched into semiconductor regions to form semiconductor channels (e.g., fin-shaped or planar channels). A base of the semiconductor channel may be in direct contact with the etch stop layer 335. The transistors may then be built around the etched semiconductor regions, e.g., depositing materials to form a gate stack, and depositing source/drain regions using low-temperature epitaxial deposition. Alternatively, a thin-film fabrication process may be used to manufacture thin film transistors (TFTs) for the transistor layer 220. A TFT is made by depositing a thin film of an active semiconductor material (e.g., the semiconductor material 302) over a supporting layer, which may be a non-conducting layer (here, the etch stop layer 335). Additional thin films may be deposited for additional features, e.g., to form a gate conductor, gate dielectric, contacts, etc. In some embodiments with back-side contacts, such as back-gated transistors, one or more interconnect layers may be deposited directly over the etch stop layer 335, and the transistor layer 220 is formed over the interconnect layer(s).

The transistors are surrounded by a second dielectric material 316, which may be any of the dielectric materials described herein. The transistors in the transistor layer 220 are coupled to conductive structures in the interconnect layers 230. The interconnect layers 230 further include the second dielectric material 316. In some embodiments, the dielectric materials 308 and 316 include the same material. In some embodiments, the transistor layer 220 and interconnect layers 230 may include different dielectric materials.

In the example of FIG. 3, the interconnect layers 230 include five interconnect layers 340a-340e. The interconnects are formed from the conductive material 306; in some embodiments, the conductive material 306 in the interconnect layers 230 may be different from the conductive material in the interconnect layer 330 of the DRAM layer 210. In addition, in some embodiments, different layers 340 of the interconnect layers 230 may have different conductive materials 306.

The interconnect layers 340 may each include one or more conductive traces and/or conductive vias, providing conductive pathways through the second dielectric material 316. Each metal layer 340 includes conductive structures, including metal lines or trenches (e.g., the line 344) formed from the conductive material 306 and vias (e.g., the via 346) formed from the conductive material 306. In general, interconnect structures, e.g., vias and metal lines, are referred to herein as conductive structures. While FIG. 3 illustrates a single conductive material 306 for the vias and the metal lines, at each metal layer, any suitable conductive material may be used, or multiple different conductive materials may be used. For example, in a given layer, different conductive materials may be used for metal lines and vias. As another example, in different layers, different materials may be used for the metal lines and/or vias, e.g., ruthenium may be included in the metal lines in the metal layers 340a and 340b, while copper is included in the metal lines in the metal layers 340c-340e. In various embodiments, conductive structures may include multiple conductive materials, e.g., a first metal as a liner, and a second metal as a fill.

Although FIG. 3 illustrates a specific number and arrangement of conductive pathways, these are simply illustrative, and any suitable number and arrangement may be used. In addition, while five metal layers 340 are illustrated in FIG. 3, the interconnect layers 230 may have fewer or more metal layers, e.g., up to 10 metal layers, up to 15 metal layers, or more.

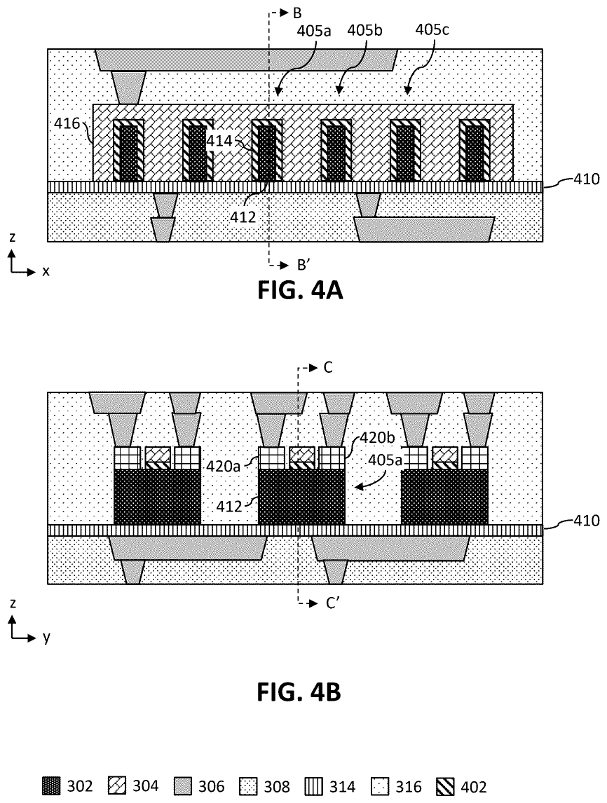

FIGS. 4-7 illustrate several detailed views or variations of the DRAM device 200.

FIGS. 4A and 4B illustrate two cross-sections of the interface between the DRAM layer and backend transistor layer, according to some embodiments of the present disclosure. Specifically, FIGS. 4A and 4B illustrate two cross-sections through the transistor layer 220, a lower portion of the interconnect layers 230, and an upper portion of the DRAM layer 210. FIG. 4B is a cross-section through the plane BB′ in FIG. 4A, and FIG. 4A is a cross-section through the plane CC′ in FIG. 4B.

In the example of FIG. 4, the transistor layer 220 includes fin-shaped transistors, also referred to as FinFETs. FinFETs are transistors having a non-planar architecture where a fin, formed of one or more semiconductor materials, extends away from a base. A gate stack that includes at least a layer of a gate electrode material and, optionally, a layer of a gate dielectric may be provided over the top and sides of the remaining upper portion of the fin (i.e., the portion above and not enclosed by the STI), thus wrapping around the upper-most portion of the fin. The portion of the fin over which the gate stack wraps around is typically referred to as a “channel portion” of the fin because this is where, during operation of the transistor, a conductive channel forms, and is a part of an active region of the fin. Two S/D regions are provided on the opposite sides of the gate stack, forming a source and a drain terminal of a transistor. FinFETs may be implemented as “tri-gate transistors,” where the name “tri-gate” originates from the fact that, in use, such transistors may form conducting channels on three “sides” of the fin. FinFETs potentially improve performance relative to single-gate transistors and double-gate transistors.

Referring specifically to FIG. 4, the transistor layer 220 includes transistors 405, e.g., 405a, 405b, and 405c. Each transistor 405 includes semiconductor material 302 that is formed in a fin-shaped structure, such as the semiconductor fin 412 of the transistor 405a. The fin 412 extends upward from the etch stop layer 410 (which is similar to the etch stop layer 335 described with respect to FIG. 3). The semiconductor fin 412 also extends in the y-direction in the orientation shown, as illustrated in FIG. 4B. When FinFETs are formed over a semiconductor substrate, typically, a portion of the fin that is closest to the base is enclosed by an insulator material. Such an insulator material, typically an oxide, is commonly referred to as a “shallow trench isolation” (STI), and the portion of the fin enclosed by the STI is typically referred to as a “subfin portion” or simply a “subfin. ” By contrast, in the example shown in FIG. 4, the semiconductor fins do not have a subfin, but instead, are formed directly on the etch stop layer 410. The semiconductor fins may be etched from a layer of the semiconductor material 302 that had been layer-transferred onto the DRAM layer 210, directly onto the etch stop layer 410. Thus, the base of the semiconductor fins are directly along the base of the transistor layer 220, and the base of the semiconductor fins are in direct contact with the etch stop layer 410. Because the DRAM layer 210 provides support for the semiconductor fins, the subfin is not needed. By contrast, if a transistor layer 220 were separately fabricated and then, the finished transistor layer 220 was layer-transferred onto the DRAM layer 210, the semiconductor fins would likely include a subfin.

The transistors 405 illustrated in FIG. 4 include a gate stack, which include a gate dielectric material 402 that wraps around a central portion of the semiconductor fins, and a gate electrode 304 that wraps around the gate dielectric material 402. For example, the gate dielectric 414 wraps around a central portion of the semiconductor fin 412, and the gate electrode 416 wraps around the gate dielectric 414. In this example, the gate electrode 416 extends across a line of semiconductor fins and electrically couples the gates together; this may be referred to as a gate line. The gate dielectric material 402 may be any of the gate dielectric materials described above, e.g., the high-k dielectric and/or the insulator material described with respect to FIG. 3.

FIG. 4B illustrates a cross-section along the fin 412 of the transistor 405a. The transistor 405a includes two S/D regions 420a and 420b arranged at different positions in the y-direction on two ends the semiconductor fin 412, and on opposite sides of the gate stack. The S/D regions 420 are examples of the S/D regions described with respect to FIG. 3.

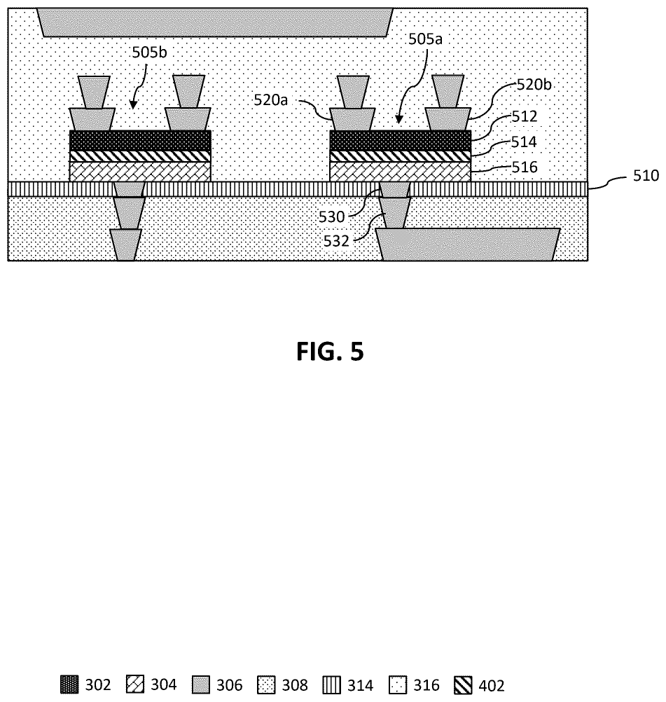

FIG. 5 illustrates an alternate transistor configuration, with a back-gated transistor. FIG. 5 is a cross-section view of another example interface between the DRAM layer and the backend transistor layer with backside contacts to the transistor layer. FIG. 5 illustrates two example transistors 505 in the transistor layer 220. In the example of FIG. 4, the source/drain contacts and gate contact were all on a front side of the transistors 405, i.e., on a side of the transistors 405 opposite the etch stop layer 410. By contrast, in the example of FIG. 5, referring to the transistor 505a, a gate 516 is on the back side of the transistor 505a, while the S/D regions 520 are on the front side of the transistor 505a. A gate dielectric 414 formed from the gate dielectric material 402 is over the gate 516, and a channel region 512 formed from the semiconductor material 302 is over the gate dielectric 514. The two S/D regions 520a and 520b are arranged at different positions along the channel region 512.

In FIG. 5, a conductive structure 530 (e.g., a via) extends through the etch stop layer 510 to electrically couple the transistor 505a to an interconnect structure in the DRAM layer 210. For example, the via may electrically couple the gate of the transistor 505a to one or more DRAM cells in the DRAM layer 210. The via 530 may be formed after the etch stop layer 510 is formed and before the transistor layer 220 is fabricated over the DRAM layer 210. Further details of the via 530 and the electrical connection between a DRAM layer 210 to the transistor layer 220 are shown in FIG. 7 and described below.

While FIG. 5 illustrates a back gated transistor, in a similar manner, a DRAM device 200 may have conductive structures through the etch stop layer to other terminals of transistors in the transistor layer 220. For example, a DRAM device 200 may have a contact through the etch stop layer coupling the interconnect layer 330 of the DRAM layer 210 to a backside S/D contact of a transistor that has one or both of the S/D regions on the back side of the transistor.

FIG. 6 is a cross-section view illustrating example interconnects through an etch stop layer of the DRAM layer, according to some embodiments of the present disclosure. FIG. 6 may illustrate details of one of the vias 334 in the DRAM layer 210 (e.g., the via 334a) and a corresponding one of the vias 342 extending through the transistor layer 220 and the etch stop layer 335 (e.g., the via 342a).

FIG. 6 shows a first via 620 within the DRAM layer 210. The first via 620 is surrounded by the first dielectric material 308. The first via 620 extends to an upper side or upper surface of the interconnect layer 330 of the DRAM layer 210, e.g., a surface opposite the support structure 150. The etch stop layer 610, which is similar to the etch stop layer 335 of FIG. 3, is over the first via 620. The first via 620 has a lower width 622 and an upper width 624. The lower width 622 is smaller than the upper width 624. The upper width 624 is the width of the first via 620 at the side of the first via 620 along the etch stop layer 610, and the lower width 622 is a width of the first via 620 at an opposite end of the first via 620, e.g., the end nearer to the support structure 150, nearer to the capacitor layer 325, and nearer to the access transistor layer 320. The first via 620 tapers in a direction away from the etch stop layer 610, e.g., in a direction towards the support structure 150, towards the capacitor layer 325, and towards to the access transistor layer 320.

FIG. 6 further shows a second via 630 that extends at least partially through the transistor layer 220 and through the etch stop layer 610. The second via 630 may further extend into the interconnect layers 230, e.g., as shown in FIG. 3. The second via 630 has a lower width 632 and an upper width 634. The lower width 632 is smaller than the upper width 634. The lower width 632 is the width of the second via 630 at the side of the second via 630 along the lower side of the etch stop layer 610. The lower width 632 is also the width of the second via 630 where the second via 630 contacts the first via 620.

Likewise, the upper width 624 is the width of the first via 620 where the first via 620 contacts the second via 630. The upper width 634 is a width of the second via 630 at an opposite end of the second via 630, e.g., the end nearer to or within the interconnect layers 230. The second via 630 tapers in a direction towards the DRAM layer 210.

The tapering and relative upper and lower widths of the first via 620 and second via 630 is due to the manufacturing process of the vias 620 and 630. When a via or interconnect is formed, it typically tapers in a direction away from the upper or outer face, i.e., the side from which the processing is performed. To form a via, regions of dielectric material (e.g., the first dielectric material 308 or the second dielectric material 316) are removed using an etching process, and then the etched areas are filled in with the conductive material 306. Typical etching processes result in tapered openings, e.g., as shown in FIG. 6. Thus, the direction of tapering can indicate the direction from which the vias were formed. In this case, the second via 630 tapering in the direction of the DRAM layer 210 indicates that the second via 630 was formed over the DRAM layer 210, using backend processing as discussed above. By contrast, if the transistor layer 220 were formed separately from the DRAM layer 210 and then bonded onto the DRAM layer 210, vias in the transistor layer 220 typically taper in the opposite direction, away from the DRAM layer 210.

FIG. 7 is a cross-section view illustrating another example of an interconnect through an etch stop layer of the DRAM layer, according to some embodiments of the present disclosure. FIG. 7 illustrates details of a first via 720, which is arranged below a transistor 712, and second via 730 that extends through an etch stop layer 710. The transistor 712 is formed over the etch stop layer 710. The second via 730 is coupled between the first via 720 and the transistor 712, similar to the configuration shown in FIG. 5. While FIG. 5 illustrates a via 530 coupled to a gate 516 of the transistor 505a, in the example of FIG. 7, the second via 730 is coupled to a region of the semiconductor material 302, e.g., a doped S/D region formed in the semiconductor material 302.

However, in other embodiments, the upper end of the second via 730 may be coupled to a different portion of a transistor, e.g., a gate electrode, or to another interconnect or contact that is coupled to a transistor formed over the etch stop layer 710.

The first via 720 is within the DRAM layer 210. The first via 720 is surrounded by the first dielectric material 308. The first via 720 extends to an upper side or upper surface of the interconnect layer 330 of the DRAM layer 210, e.g., a surface opposite the support structure 150. The etch stop layer 710, which is similar to the etch stop layer 335 of FIG. 3, is over the first via 720. The first via 720 has a lower width 722 and an upper width 724. The lower width 722 is smaller than the upper width 724. The upper width 724 is the width of the first via 720 at the side of the first via 720 along the etch stop layer 710, and the lower width 722 is a width of the first via 720 at an opposite end of the first via 720, e.g., the end nearer to the support structure 150, nearer to the capacitor layer 325, and nearer to the access transistor layer 320. The first via 720 tapers in a direction away from the etch stop layer 710, e.g., in a direction towards the support structure 150, towards the capacitor layer 325, and towards to the access transistor layer 320.

The second via 730 that extends through the etch stop layer 710. In some embodiments, the second via 730 may further extend into the transistor layer 220, or in some cases, in an interconnect layer between the etch stop layer 710 and the transistor layer 220. The second via 730 has a lower width 732 and an upper width 734. The lower width 732 is smaller than the upper width 734. The lower width 732 is the width of the second via 730 at the side of the second via 730 along the lower side of the etch stop layer 710. The lower width 732 is also the width of the second via 730 where the second via 730 contacts the first via 720. Likewise, the upper width 724 is the width of the first via 720 where the first via 720 contacts the second via 730. The upper width 734 is a width of the second via 730 at an opposite end of the second via 730, e.g., the end along the lower side of the transistor layer 220. The second via 730 tapers in a direction towards the DRAM layer 210 and in a direction away from the transistor layer 220.

As described with respect to FIG. 6, the tapering of the vias indicates that the second via 730 was fabricated over the DRAM layer 210. The transistor layer 220 and/or interconnect layers 230 also include vias that taper in the same direction, towards the DRAM layer 210, as described with respect to FIG. 6 and illustrated in FIGS. 3-5.

### Example Devices

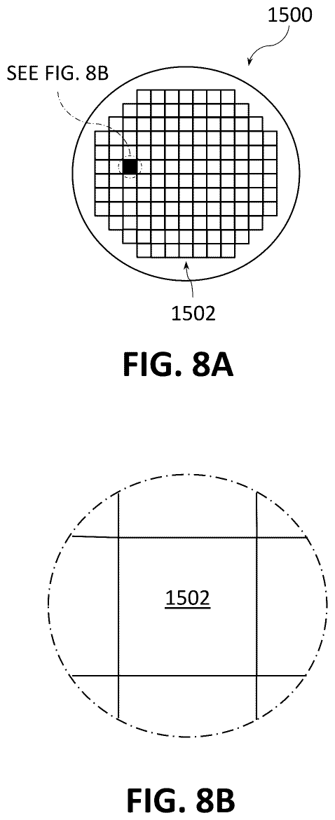

The DRAM device with backend transistors disclosed herein may be included in any suitable electronic device. FIGS. 8-11 illustrate various examples of apparatuses that may include, or be included in, the DRAM devices disclosed herein.

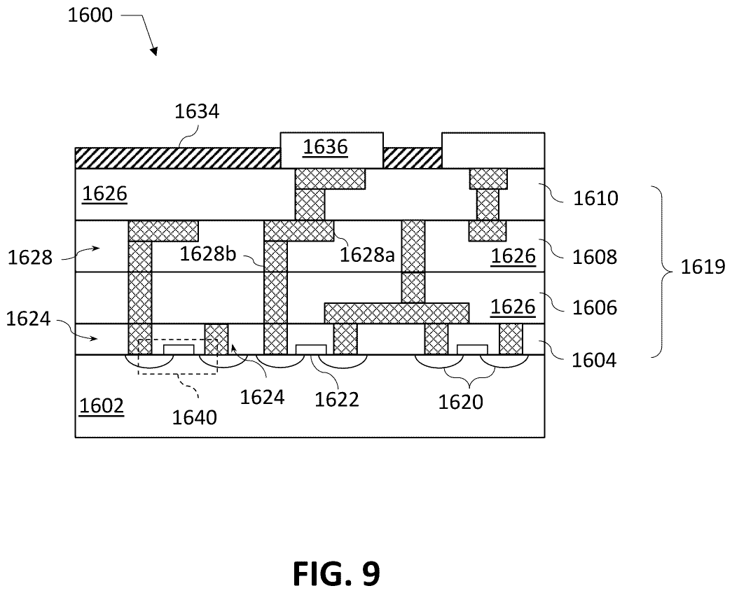

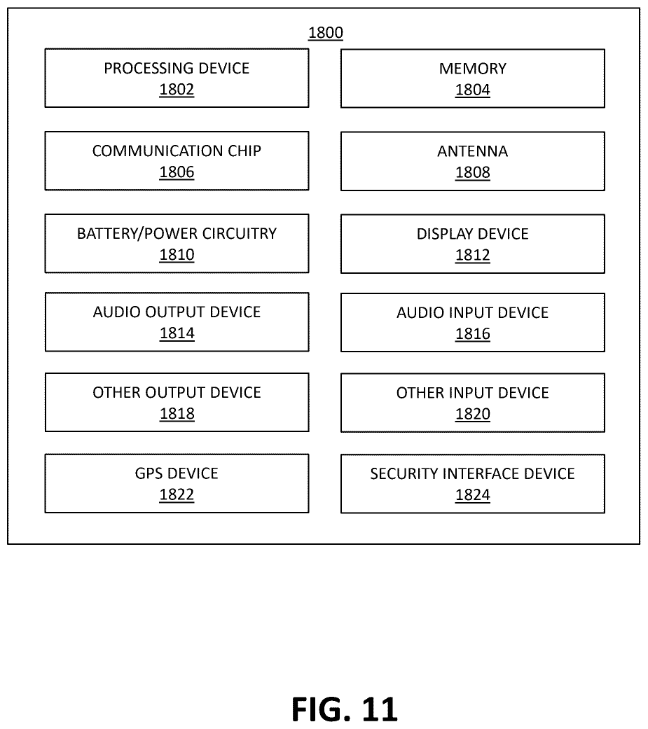

FIGS. 8A and 8B are top views of a wafer and dies that include, or may be used to fabricate, one or more IC structures including one or more DRAM device with backend transistors in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 1-5, or any further embodiments of the IC structures described herein). After the fabrication of the semiconductor product is complete (e.g., after manufacture of one or more IC structures with one or more of the transistors as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more of the transistors as disclosed herein may take the form of the wafer 1500 (e.g., not singulated) or the form of the die 1502 (e.g., singulated). The die 1502 may include one or more transistors (e.g., one or more of the transistors 1640 of FIG. 9, discussed below) and/or supporting circuitry to route electrical signals to the transistors, as well as any other IC components (e.g., one or more of the non-planar transistors described herein). In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 11) or other logic that is configured to store information in the memory devices or execute instructions stored in the memory array.

FIG. 9 is a cross-sectional side view of an IC device 1600 that may be used in a DRAM device with backend transistors in accordance with any of the embodiments disclosed herein. The IC device 1600 may be formed on a substrate 1602 (e.g., the wafer 1500 of FIG. 8A) and may be included in a die (e.g., the die 1502 of FIG. 8B). The substrate 1602 may be any substrate as described herein. The substrate 1602 may be part of a singulated die (e.g., the dies 1502 of FIG. 8B) or a wafer (e.g., the wafer 1500 of FIG. 8A).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 9 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 9). Although a particular number of interconnect layers 1606-1610 is depicted in FIG. 9, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 9. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 9. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

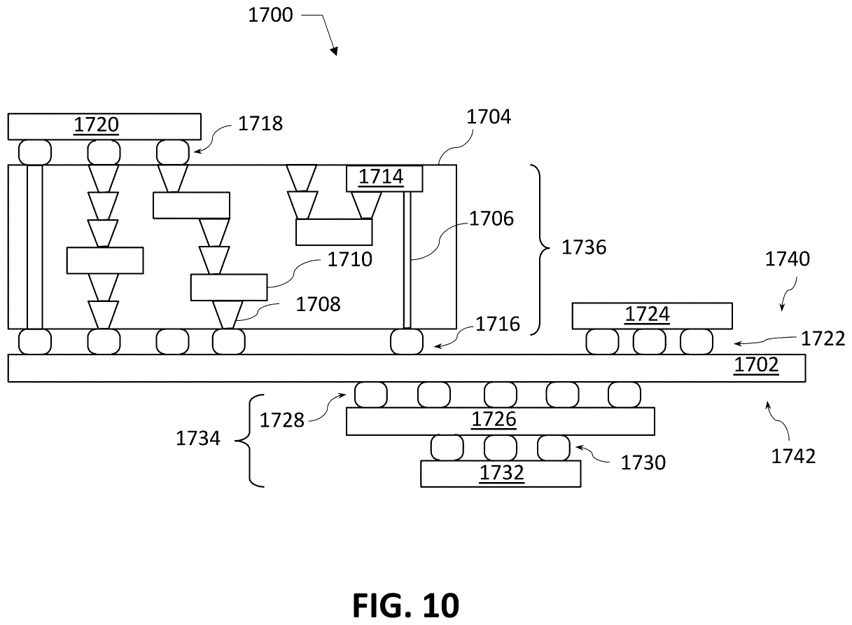

FIG. 10 is a cross-sectional side view of an IC device assembly 1700 that may include components having or being associated with (e.g., being electrically connected by means of) one or more DRAM devices with backend transistors in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include one or more of the non-planar transistors disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 10 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 10), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 10, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 8B), an IC device (e.g., the IC device 1600 of FIG. 9), or any other suitable component. In some embodiments, the IC package 1720 may include one or more DRAM devices with backend transistors, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 10, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 10 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 11 is a block diagram of an example computing device 1800 that may include one or more DRAM devices with backend transistors in accordance with any of the embodiments disclosed herein. For example, any suitable ones of the components of the computing device 1800 may include a die (e.g., the die 1502 (FIG. 8B)) that is or includes a DRAM device with backend transistors. Any one or more of the components of the computing device 1800 may include, or be included in, an IC device 1600 (FIG. 9). Any one or more of the components of the computing device 1800 may include, or be included in, an IC device assembly 1700 (FIG. 10).

A number of components are illustrated in FIG. 11 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 11, but the computing device 1800 may include interface circuitry for coupling to the one or more components. For example, the computing device 1800 may not include a display device 1812, but may include display device interface circuitry (e.g., a connector and driver circuitry) to which a display device 1812 may be coupled.

In another set of examples, the computing device 1800 may not include an audio input device 1816 or an audio output device 1814, but may include audio input or output device interface circuitry (e.g., connectors and supporting circuitry) to which an audio input device 1816 or audio output device 1814 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the computing device 1800 may include a communication chip 1806 (e.g., one or more communication chips). For example, the communication chip 1806 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1806 may implement any of a number of wireless standards or protocols, including but not limited to Institute for Electrical and Electronic Engineers (IEEE) standards including Wi-Fi (IEEE 1402.11 family), IEEE 1402.18 standards (e.g., IEEE 1402.18-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.18 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.18 standards. The communication chip 1806 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1806 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1806 may operate in accordance with other wireless protocols in other embodiments. The computing device 1800 may include an antenna 1808 to facilitate wireless communications and/or to receive other wireless communications (such as AM or FM radio transmissions).

In some embodiments, the communication chip 1806 may manage wired communications, such as electrical, optical, or any other suitable communication protocols (e.g., the Ethernet). As noted above, the communication chip 1806 may include multiple communication chips. For instance, a first communication chip 1806 may be dedicated to shorter-range wireless communications such as Wi-Fi or Bluetooth, and a second communication chip 1806 may be dedicated to longer-range wireless communications such as GPS, EDGE, GPRS, CDMA, WiMAX, LTE, EV-DO, or others. In some embodiments, a first communication chip 1806 may be dedicated to wireless communications, and a second communication chip 1806 may be dedicated to wired communications.

The computing device 1800 may include a battery/power circuitry 1810. The battery/power circuitry 1810 may include one or more energy storage devices (e.g., batteries or capacitors) and/or circuitry for coupling components of the computing device 1800 to an energy source separate from the computing device 1800 (e.g., AC line power).

The computing device 1800 may include a display device 1812 (or corresponding interface circuitry, as discussed above). The display device 1812 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1814 (or corresponding interface circuitry, as discussed above). The audio output device 1814 may include any device that generates an audible indicator, such as speakers, headsets, or earbuds, for example.

The computing device 1800 may include an audio input device 1816 (or corresponding interface circuitry, as discussed above). The audio input device 1816 may include any device that generates a signal representative of a sound, such as microphones, microphone arrays, or digital instruments (e.g., instruments having a musical instrument digital interface (MIDI) output).

The computing device 1800 may include another output device 1818 (or corresponding interface circuitry, as discussed above). Examples of the other output device 1818 may include an audio codec, a video codec, a printer, a wired or wireless transmitter for providing information to other devices, or an additional storage device.

The computing device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may include a global positioning system (GPS) device 1822 (or corresponding interface circuitry, as discussed above).

The GPS device 1822 may be in communication with a satellite-based system and may receive a location of the computing device 1800, as known in the art.

The computing device 1800 may include a security interface device 1824. The security interface device 1824 may include any device that provides security features for the computing device 1800 or for any individual components therein (e.g., for the processing device 1802 or for the memory 1804). Examples of security features may include authorization, access to digital certificates, access to items in keychains, etc. Examples of the security interface device 1824 may include a software firewall, a hardware firewall, an antivirus, a content filtering device, or an intrusion detection device.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### Select Examples

The following paragraphs provide various examples of the embodiments disclosed herein.

Example 1 provides a device including a dynamic random-access memory (DRAM) layer having a first side and a second side, the DRAM layer including a capacitor; and a first interconnect structure, where the first interconnect structure has a first end nearer to the first side of the DRAM layer and a second end nearer to the second side of the DRAM layer, where the first end is wider than the second end; and a transistor layer over the DRAM layer, the transistor layer having a first side and a second side, the first side of the transistor layer coupled to the first side of the DRAM layer, the transistor layer including a second interconnect structure, where the second interconnect structure has a third end nearer to the first side of the transistor layer and a fourth end nearer to the second side of the transistor layer, and the fourth end is wider than the third end.

Example 2 provides the device of example 1, where the DRAM layer includes an etch stop layer along at least a portion of the first side of the DRAM layer.

Example 3 provides the device of example 2, where the second interconnect structure in the transistor layer extends through the etch stop layer of the DRAM layer.

Example 4 provides the device of example 3, where the second interconnect structure is coupled to the first interconnect structure of the DRAM layer.

Example 5 provides the device of any of examples 1-4, where the transistor layer includes a transistor, the transistor has a fin-shaped semiconductor region.

Example 6 provides the device of example 5, where a base of the fin-shaped semiconductor region is directly on the first side of the DRAM layer.

Example 7 provides the device of any of examples 1-6, the DRAM layer further including a transistor coupled to the capacitor, the transistor and the capacitor forming a DRAM cell.

Example 8 provides the device of example 7, where the capacitor is between the transistor and the first side of the DRAM layer.

Example 9 provides the device of any of examples 1-8, where the first interconnect structure is a first via, and the second interconnect structure is a second via.

Example 10 provides a device including a dynamic random-access memory (DRAM) layer having a first side and a second side, the DRAM layer including a plurality of capacitors; and an etch stop layer over the plurality of capacitors, the etch stop layer along the first side of the DRAM layer; and a transistor layer over the DRAM layer, the transistor layer having a first side and a second side, the first side of the transistor layer in direct contact with the etch stop layer of the DRAM layer.

Example 11 provides the device of example 10, where the transistor layer includes a transistor having a semiconductor region having a base along the first side of the transistor layer.

Example 12 provides the device of example 11, where the base of the semiconductor region is in direct contact with the etch stop layer of the DRAM layer.

Example 13 provides the device of example 11 or 12, where the semiconductor region is a fin.

Example 14 provides the device of any of examples 10-13, where the transistor layer includes a set of transistors arranged as a static random-access memory (SRAM) cell.

Example 15 provides the device of example 14, where the SRAM cell is configured to implement an SRAM tag to index memory locations in the DRAM layer.

Example 16 provides the device of any of examples 10-13, where the DRAM layer includes an access transistor coupled to a capacitor, and the transistor layer includes a transistor coupled to a gate of the access transistor.

Example 17 provides the device of example 16, where the transistor is configured to control power delivery to the access transistor.

Example 18 provides a package including a packaging component; and a dynamic random-access memory (DRAM) device coupled to the packaging component, the DRAM device including a DRAM layer having a capacitor and a first interconnect structure; and a transistor layer over the DRAM layer, the transistor layer having a transistor and a second interconnect structure, where the first interconnect structure tapers in a direction away from the transistor layer, and the second interconnect structure tapers in a direction away from the DRAM layer.

Example 19 provides the package of example 18, where the DRAM layer includes an etch stop layer, the transistor layer is over the etch stop layer, and the second interconnect structure extends at least partially into the etch stop layer.

Example 20 provides the package of example 19, where the transistor of the transistor layer is in direct contact with the etch stop layer.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A device comprising:
a dynamic random-access memory (DRAM) layer having a first side and a second side, the DRAM layer comprising:
a capacitor; and
a first interconnect structure, wherein the first interconnect structure has a first end nearer to the first side of the DRAM layer and a second end nearer to the second side of the DRAM layer, wherein the first end is wider than the second end; and
a transistor layer over the DRAM layer, the transistor layer having a first side and a second side, the first side of the transistor layer coupled to the first side of the DRAM layer, the transistor layer comprising a second interconnect structure, wherein the second interconnect structure has a third end nearer to the first side of the transistor layer and a fourth end nearer to the second side of the transistor layer, and the fourth end is wider than the third end.

2. The device of claim 1, wherein the DRAM layer comprises an etch stop layer along at least a portion of the first side of the DRAM layer.

3. The device of claim 2, wherein the second interconnect structure in the transistor layer extends through the etch stop layer of the DRAM layer.

4. The device of claim 3, wherein the second interconnect structure is coupled to the first interconnect structure of the DRAM layer.

5. The device of claim 1, wherein the transistor layer comprises a transistor, the transistor has a fin-shaped semiconductor region.

6. The device of claim 5, wherein a base of the fin-shaped semiconductor region is directly on the first side of the DRAM layer.

7. The device of claim 1, the DRAM layer further comprising a transistor coupled to the capacitor, the transistor and the capacitor forming a DRAM cell.

8. The device of claim 7, wherein the capacitor is between the transistor and the first side of the DRAM layer.

9. The device of claim 1, wherein the first interconnect structure is a first via, and the second interconnect structure is a second via.

10. A device comprising:
a dynamic random-access memory (DRAM) layer having a first side and a second side, the DRAM layer comprising:
a plurality of capacitors; and
an etch stop layer over the plurality of capacitors, the etch stop layer along the first side of the DRAM layer; and
a transistor layer over the DRAM layer, the transistor layer having a first side and a second side, the first side of the transistor layer in direct contact with the etch stop layer of the DRAM layer.

11. The device of claim 10, wherein the transistor layer comprises a transistor having a semiconductor region having a base along the first side of the transistor layer.

12. The device of claim 11, wherein the base of the semiconductor region is in direct contact with the etch stop layer of the DRAM layer.

13. The device of claim 11, wherein the semiconductor region is a fin.

14. The device of claim 10, wherein the transistor layer comprises a set of transistors arranged as a static random-access memory (SRAM) cell.

15. The device of claim 14, wherein the SRAM cell is configured to implement an SRAM tag to index memory locations in the DRAM layer.

16. The device of claim 10, wherein the DRAM layer comprises an access transistor coupled to a capacitor, and the transistor layer comprises a transistor coupled to a gate of the access transistor.

17. The device of claim 16, wherein the transistor is configured to control power delivery to the access transistor.

18. A package comprising:
a packaging component; and
a dynamic random-access memory (DRAM) device coupled to the packaging component, the DRAM device comprising:
a DRAM layer comprising a capacitor and a first interconnect structure; and
a transistor layer over the DRAM layer, wherein the transistor layer comprises a transistor and a second interconnect structure, wherein the first interconnect structure tapers in a direction away from the transistor layer, and the second interconnect structure tapers in a direction away from the DRAM layer.

19. The package of claim 18, wherein the DRAM layer comprises an etch stop layer, the transistor layer is over the etch stop layer, and the second interconnect structure extends at least partially into the etch stop layer.

20. The package of claim 19, wherein the transistor of the transistor layer is in direct contact with the etch stop layer.
